(19) United States
(12) Patent Application Publication
(10) Pub. No.: US 2026/0026090 A1
(43) Pub. Date: Jan. 22, 2026

(54) SEMICONDUCTOR DEVICE AND METHOD FOR MANUFACTURING THE SAME

(71) Applicant: Samsung Electronics Co., Ltd., Suwon-si (KR)

(72) Inventors: Jina KIM, Suwon-si (KR); YOUNGGWON KIM, Suwon-si (KR); JONG PIL KIM, Suwon-si (KR); Yunyeong YI, Suwon-si (KR)

(21) Appl. No.: 19/028,517

(22) Filed: Jan. 17, 2025

(30) Foreign Application Priority Data
Jul. 18, 2024 (KR) 10-2024-0095074

(51) Int. Cl. H10D 84/83; H10D 30/00; H10D 30/01; H10D 62/10; H10D 62/13; H10D 62/60; H10D 62/832; H10D 84/01

(52) U.S. Cl. CPC H10D 84/8312; H10D 30/503; H10D 30/506; H10D 62/121; H10D 62/151; H10D 62/60; H10D 62/832; H10D 84/8311; H10D 84/832; H10D 30/0194; H10D 84/0128; H10D 84/013

(57) ABSTRACT

Provided is a semiconductor device including a first active pattern and a second active pattern on a substrate, a first source/drain pattern and a first channel pattern on the first active pattern, a second source/drain pattern and a second channel pattern on the second active pattern, and a gate electrode crossing each of the first channel pattern and the second channel pattern. Along a horizontal extension direction of the gate electrode, a first width of an upper surface of the first channel pattern is greater than a second width of an upper surface of the second channel pattern, and an upper surface of the first source/drain pattern is located at a vertically higher level than the upper surface of the first channel pattern.

### CROSS-REFERENCE TO RELATED APPLICATIONS

This U.S. non-provisional patent application claims priority under 35 U.S.C. § 119 of Korean Patent Application No. 10-2024-0095074, filed on Jul. 18, 2024, the entire contents of which are hereby incorporated by reference.

### BACKGROUND

The present disclosure herein relates to a semiconductor device and a method for manufacturing the same, and more particularly, to a semiconductor device including a field effect transistor and a method for manufacturing the same.

A semiconductor device includes an integrated circuit composed of metal-oxide-semiconductor field effect transistors (MOSFET). As the size and the design rule of the semiconductor device are gradually decreasing, scaling down of the metal-oxide-semiconductor field effect transistors is also gradually being accelerated. As the metal-oxide-semiconductor field effect transistors are gradually scaled down, operation characteristics of the semiconductor device may be deteriorated. Accordingly, research on various methods for overcoming limitations caused by high-integration of the semiconductor device and forming the semiconductor device with more excellent performance is being conducted.

### SUMMARY

The present disclosure provides a semiconductor device with improved productivity and a method for manufacturing the same.

The present disclosure also provides a semiconductor device with improved electrical characteristics and a method for manufacturing the same.

A technical goal of the inventive concept is not limited to the goal mentioned above, and other technical goals that are not mentioned may be clearly understood from description below by those skilled in the art.

An embodiment of the inventive concept provides a semiconductor device including a first active pattern and a second active pattern provided with a substrate, a first source/drain pattern and a first channel pattern on the first active pattern, a second source/drain pattern and a second channel pattern on the second active pattern, and a gate electrode crossing each of the first channel pattern and the second channel pattern, wherein along a horizontal extension direction of the gate electrode, a first width of an upper surface of the first channel pattern is greater than a second width of an upper surface of the second channel pattern, and an upper surface of the first source/drain pattern is located at a vertically higher level than the upper surface of the first channel pattern.

In an embodiment of the inventive concept, a semiconductor device includes a first active pattern and a second active pattern provided with a substrate, a first source/drain pattern and a first channel pattern on the first active pattern, a second source/drain pattern and a second channel pattern on the second active pattern, and a gate electrode crossing each of the first channel pattern and the second channel pattern, wherein along a horizontal extension direction of the gate electrode, a first width of an upper surface of the first channel pattern is smaller than a second width of an upper surface of the second channel pattern, and an upper surface of the first source/drain pattern is located at a vertically higher level than the upper surface of the first channel pattern.

In an embodiment of the inventive concept, a semiconductor device includes a first active pattern and a second active pattern provided with a substrate, a first source/drain pattern and a first channel pattern on the first active pattern, a second source/drain pattern and a second channel pattern on the second active pattern, a gate electrode crossing each of the first and second channel patterns, a first interlayer insulating layer on the first source/drain pattern and the second source/drain pattern, and an active contact penetrating the first interlayer insulating layer and connected to at least one of the first source/drain pattern or the second source/drain pattern, wherein along a horizontal extension direction of the gate electrode, a first width of an upper surface of the first channel pattern is greater than a second width of an upper surface of the second channel pattern, and an upper surface of the first source/drain pattern is located at a vertically higher level than the upper surface of the first channel pattern.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view illustrating a semiconductor device according to some embodiments of the inventive concept;

FIG. 2 is a cross-sectional view taken along line A-A′, line B-B′ and line C-C′ of FIG. 1;

FIG. 3 is a cross-sectional view taken along line D-D′, line E-E′ and line F-F′ of FIG. 1; and

FIGS. 4A, 4B, 5A, 5B, 6 to 7 are diagrams illustrating a method for manufacturing a semiconductor device according to some embodiments of the inventive concept.

### DETAILED DESCRIPTION

Hereinafter, embodiments of the inventive concept will be described with reference to the accompanying drawings in more detail in order to more specifically describe the inventive concept.

Items described in the singular herein may be provided in plural, as can be seen, for example, in the drawings. Thus, the description of a single item that is provided in plural should be understood to be applicable to the remaining plurality of items unless context indicates otherwise.

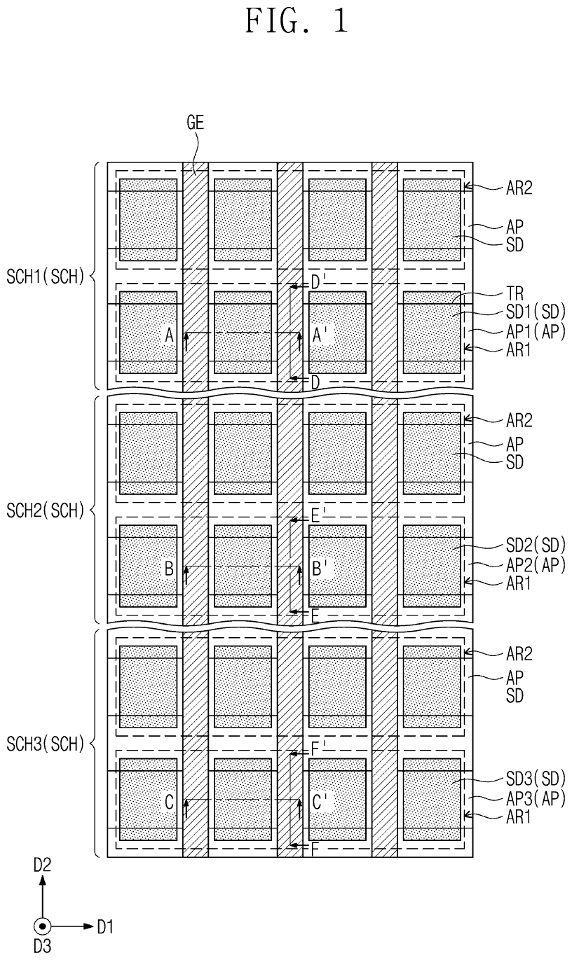

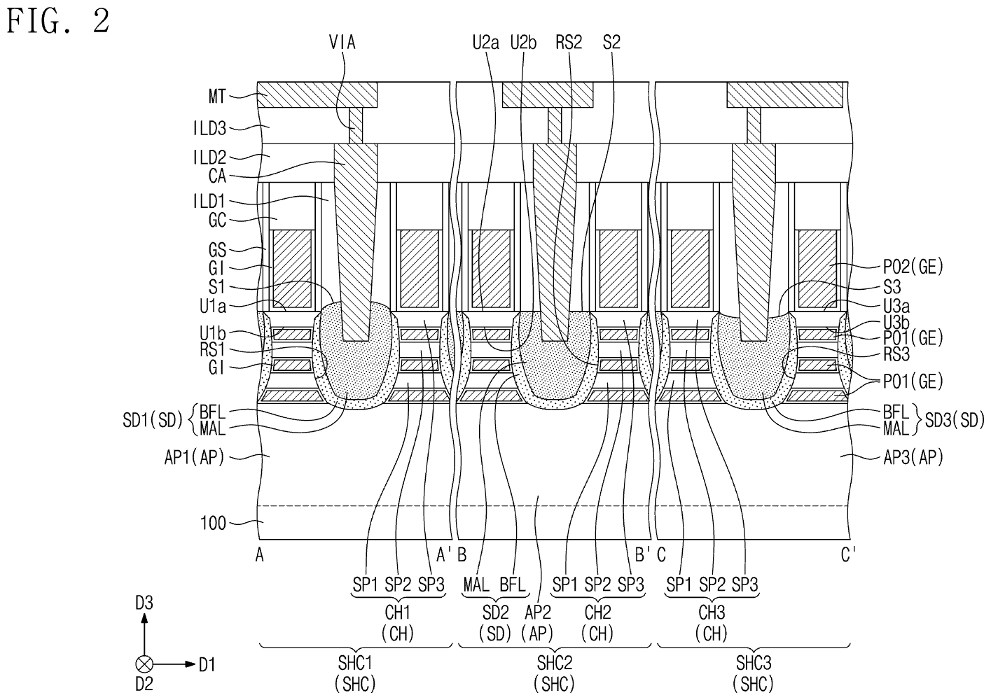

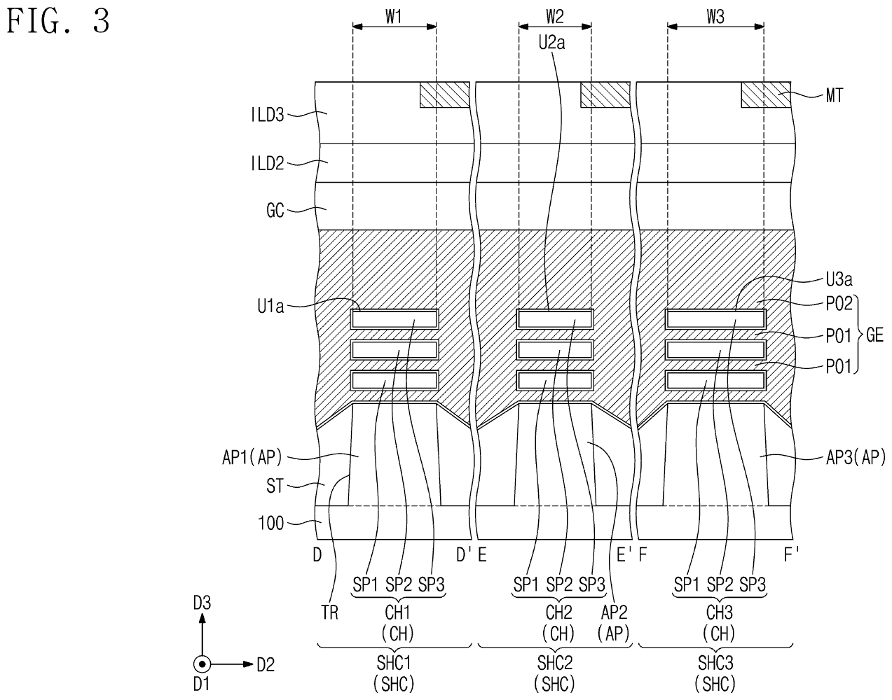

FIG. 1 is a plan view illustrating a semiconductor device according to some embodiments of the inventive concept. FIG. 2 is a cross-sectional view taken along line A-A′, line B-B′ and line C-C′ of FIG. 1. FIG. 3 is a cross-sectional view taken along line D-D′, line E-E′ and line F-F′ of FIG. 1.

Referring to FIGS. 1 to 3, a substrate 100 including a single height cell SHC may be provided. For example, the substrate 100 may be a semiconductor substrate or compound semiconductor substrate including at least one of silicon, germanium, or silicon-germanium.

In the present disclosure, each of the wordings, “A or B”, “at least one of A and B”, “at least one of A or B”, “A, B or C”, “at least one of A, B and C” and “at least one of A, B or C” may include any one or all possible combinations among items listed together with the corresponding phrase therein. Further, throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

For another example, the substrate 100 may be an insulating substrate including an insulating material. For example, the substrate 100 may have a shape of a plate extending along a first direction D1 and a second direction D2. The first direction D1 and the second direction D2 may be parallel to an upper surface of the substrate 100 and may cross each other.

The single height cell SHC may constitute one logic cell. In the present disclosure, the logic cell may mean a logic element (for example, AND, OR, XOR, XNOR, an inverter, or the like) that performs a specific function. For example, the logic cell may include transistors for constituting the logic element and lines connecting the transistors to each other.

The single height cell SHC may include a first single height cell SHC1, a second single height cell SHC2 and a third single height cell SHC3. Three single height cells are illustrated in the drawing, but three or more single height cells may be provided. It is illustrated that the first single height cell SHC1, the second single height cell SHC2 and the third single height cell SHC3 are disposed along the first direction D1, but the inventive concept is not limited thereto. The first single height cell SHC1, the second single height cell SHC2 and the third single height cell SHC3 may be disposed in various directions parallel to an upper surface of the substrate 100.

The first single height cell SHC1, the second single height cell SHC2 and the third single height cell SHC3 may include a first active region AR1 and a second active region AR2, respectively. For example, the first active region AR1 may be a PMOSFET region, and the second active region AR2 may be an NMOSFET region.

An active pattern AP may be provided as a part of each of the first single height cell SHC1, the second single height cell SHC2 and the third single height cell SHC3. It is illustrated that the active pattern AP extends along the first direction D1, but the inventive concept is not limited thereto. The active pattern AP may be defined by a trench TR disposed at an upper portion of the substrate 100. The substrate 100 and the active pattern AP may have material continuity or may not. Reference to the substrate 100 being provided with the active pattern AP or reference to the active pattern AP being provided with the substrate 100 are intended to encompass these alternatives. Accordingly, as used herein, the term “substrate” should not be interpreted as requiring materially distinctiveness from the active pattern AP. For example, when the substrate 100 includes a semiconductor substrate, the active pattern AP may be a portion of the substrate 100. For example, the portion of the substrate 100 may protrude in a third direction D3. The third direction D3 may be a direction vertical (or perpendicular) to an upper surface of the substrate 100. Spatially relative terms, such as “vertical,” horizontal,” “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

The active patterns AP may include a pair of active patterns AP disposed spaced apart from each other on (or in) each of the single height cell SHC in a direction crossing an extension direction of the active pattern AP. One of the pair of active patterns AP may be provided on (or in) the first active region AR1, and the other thereof may be provided on the second active region AR2.

Here, the active pattern AP provided on the first active region ARI of the first single height cell SHC1 is referred to as a first active pattern AP1. The active pattern AP provided on the first active region AR1 of the second single height cell SHC2 is referred to as a second active pattern AP2. The active pattern AP provided on the first active region ARI of the third single height cell SHC3 is referred to as a third active pattern AP3.

It is illustrated that the first active pattern AP1, the second active pattern AP2 and the third active pattern AP3 each extend along the first direction D1, but the inventive concept is not limited thereto. The first active pattern AP1, the second active pattern AP2 and the third active pattern AP3 may extend along various directions parallel to the upper surface of the substrate 100.

An element isolation pattern ST may be provided on the substrate 100, and may fill the trench TR. For example, the element isolation pattern ST may include an insulating material.

A channel pattern CH may be provided on the active pattern AP. The channel pattern CH may be provided in plurality in each of the active regions. The channel patterns CH in each of the active regions may be vertically stacked. The channel pattern CH may be provided on the active pattern AP of the first active region AR1 and the active pattern AP of the second active region AR2. The channel patterns CH on the first active region AR1 may be disposed spaced apart from each other along the first direction D1. The channel patterns CH on the second active region AR2 may be disposed spaced apart from each other along the first direction D2. The channel pattern CH may include a first semiconductor pattern SP1, a second semiconductor pattern SP2 and a third semiconductor pattern SP3 disposed spaced apart from each other in the third direction D3, but the inventive concept is not limited thereto. For example, the channel pattern CH may include at least four semiconductor patterns. For example, each of the first to third semiconductor patterns SP1, SP2, and SP3 may include crystalline silicon.

Here, the channel pattern CH provided on the first active pattern AP1 of the first single height cell SHC1 is referred to as a first channel pattern CH1. The channel pattern CH provided on the second active pattern AP2 of the second single height cell SHC2 is referred to as a second channel pattern CH2. The channel pattern CH provided on the third active pattern AP3 of the third single height cell SHC3 is referred to as a third channel pattern CH3.

Along a direction parallel to the upper surface of the substrate 100, and crossing an extension direction of the first active pattern AP1, an upper surface Ula of the first channel pattern CH1 may have a first width W1. Along a direction parallel to the upper surface of the substrate 100, and crossing an extension direction of the second active pattern AP2, an upper surface U2a of the second channel pattern CH2 may have a second width W2. Along a direction parallel to the upper surface of the substrate 100, and crossing an extension direction of the third active pattern AP3, an upper surface U3a of the third channel pattern CH3 may have a third width W3. In the present disclosure, the upper surface of the channel pattern CH may mean an upper surface of an uppermost semiconductor pattern among the semiconductor patterns SP1, SP2, and SP3 in each of the active regions.

The first width W1 may be greater than the second width W2, and may be smaller than the third width W3. Since the first to third widths W1, W2 and W3 are different from each other, the first active region ARI of the first single height cell SHC1, the first active region ARI of the second single height cell SHC2 and the first active region ARI of the third single height cell SHC3 may have different roles or characteristics from each other. For example, a single height cell of the semiconductor device may include transistors. Each width of the transistors is one of the first to third widths W1, W2 and W3. The widths may be determined based on the required performance of the single height cell.

First recesses RS1 may be defined (interposed) between the first channel patterns CH1. Second recesses RS2 may be defined between the second channel patterns CH2. Third recesses RS3 may be defined between the third channel patterns CH3. Although not shown, a recess having the same shape as or a similar shape to the recesses shown in FIG. 2 may be defined between the channel patterns CH of the second active region AR2 of the single height cell SHC such that the first recesses RS1, the second recesses RS2 or the third recesses RS3 may be interposed between the first channel patterns CH1, between the second channel patterns CH2, or between the third channel patterns CH3, in each of the second active regions AR2.

Source/drain patterns SD may be provided on the active patterns AP. Each of the source/drain patterns SD may fill a corresponding one of the first to third recesses RS1, RS2 and RS3 in the first and second active regions ARI and AR2. Each of the source/drain patterns SD may be connected to a corresponding set of the first to third semiconductor patterns SP1, SP2, and SP3 in each of the first and second active regions AR1 and AR2.

The source/drain pattern SD provided on (or with) the first active pattern API may be an impurity region (e.g., a region doped with impurities (charge carrier dopants)) having a first conductive type (for example, a P-type). The source/drain pattern SD provided on the first active pattern API may include a semiconductor element (for example, silicon germanium (SiGe)) having a greater lattice parameter than a semiconductor element of each of the first to third channel patterns CH1, CH2 and CH3. For example, in each of the first active regions AR1, a source/drain pattern SD provided may be formed of a first semiconductor material (e.g., SiGe). The first to third channel patterns CH1, CH2 and CH3, which are connected to the source/drain pattern SD, may be formed of a second material (e.g., silicon). The first semiconductor material may have greater lattice constant than the second semiconductor material. Accordingly, a pair of source/drain patterns SD provided on the first active pattern API may supply a compressive stress to the channel pattern CH therebetween. For example, because germanium has a larger lattice constant compared to silicon, the lattice constant may increase as the concentration of germanium increases in SiGe alloys. Silicon (the first to third channel patterns CH1, CH2 and CH3) and SiGe (source/drain pattern SD) may have different lattice constants. Accordingly, the volume or height of the source/drain patterns SD as well as such amount of lattice mismatch may affect the microstructure and electrical properties of the transistors.

The source/drain pattern SD provided on the first active pattern AP1 may include a buffer layer BFL covering an inner surface of each of the first to third recesses RS1, RS2 and RS3 and a main layer MAL on the buffer layer BFL. The buffer layer BFL may be disposed to partially surround the main layer MAL. For example, the buffer layer BFL and the main layer MAL may each include silicon-germanium (SiGe). The buffer layer BFL may have a relatively low concentration of germanium (Ge). The main layer MAL may have a relatively high concentration of germanium (Ge). For another example, the buffer layer BFL may contain only silicon (Si), while the main layer MAL is formed of SiGe.

The substrate 100, the active pattern AP and the source/drain pattern SD provided on the second active pattern AP2 may have material continuity. For example, the source/drain pattern SD provided on the second active pattern AP2 may be an impurity region having a first conductive type (for example, an N-type Si), while the active pattern AP and the source/drain pattern SD provided on the second active pattern AP2 may be formed of Si. For example, the source/drain pattern SD provided on the second active pattern AP2 may include the same semiconductor element (for example, Si) as the substrate 100.

Here, the source/drain patterns SD provided on the first active pattern AP1 of the first single height cell SHC1 is referred to as a first source/drain pattern SD1. The source/drain patterns SD provided on the second active pattern AP2 of the second single height cell SHC2 is referred to as a second source/drain pattern SD2. The source/drain patterns SD provided on the third active pattern AP3 of the third single height cell SHC3 is referred to as a third source/drain pattern SD3.

The first source/drain pattern SD1 may fill the first recess RS1. The second source/drain pattern SD2 may fill the second recess RS2. The third source/drain pattern SD3 may fill the third recess RS3.

The first source/drain pattern SD1 may have a first upper surface S1. The second source/drain pattern SD2 may have a second upper surface S2. The third source/drain pattern SD3 may have a third upper surface S3. In the present disclosure, the upper surface of the source/drain pattern may mean an upper surface of the main layer MAL of the source/drain pattern. The first upper surface S1 may be located at a vertically higher level than the upper surface Ula of the first channel pattern CH1. The second upper surface S2 may be located at the substantially vertically same level (located substantially at the same vertical level) as the upper surface U2a of the second channel pattern CH2. The third upper surface S3 may be located at a vertically lower level than the upper surface U3a of the third channel pattern CH3. The third upper surface S3 may be located at a higher level than a lower surface U3b of an uppermost semiconductor pattern among the semiconductor patterns SP1, SP2, and SP3 of the third channel pattern CH3. The first upper surface S1 may be located at a vertically higher level than each of the second upper surface S2 and the third upper surface S3. The second upper surface S2 may be located at a vertically higher level than the third upper surface S3.

Terms such as “same,” “equal,” “planar,” or “coplanar,” as used herein when referring to orientation, layout, location, shapes, sizes, compositions, amounts, or other measures do not necessarily mean an exactly identical orientation, layout, location, shape, size, composition, amount, or other measure, but are intended to encompass nearly identical orientation, layout, location, shapes, sizes, compositions, amounts, or other measures within typical variations that may occur resulting from conventional manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes.

The first upper surface S1 may have a convex upward profile. The third upper surface S3 may have a concave downward profile. For example, the third upper surface S3 may be disposed below the upper surface U3a of the third channel pattern CH3 and recessed toward the substrate 100, while the first upper surface S1 may protrude beyond the upper surface Ula of the first channel pattern CH1. For example, the second upper surface S2 may be disposed substantially at the same vertical height level as the upper surface U2a of the second channel pattern CH2.

Along a horizontal direction, at the vertically same level, a width of the first source/drain pattern SD1 may be greater than a width of the second source/drain pattern SD2, and may be smaller than a width of the third source/drain pattern SD3. For example, along an extension direction of a gate electrode GE (to be described later), at the height levels of lower surfaces U1b, U2b and U3b of the third semiconductor pattern SP3, a width of the first source/drain pattern SD1 may be greater than a width of the second source/drain pattern SD2, and may be smaller than a width of the third source/drain pattern SD3.

For example, along a vertical direction, a height of the first source/drain pattern SD1 may be greater than a height of the second source/drain pattern SD2, and an height of the second source/drain pattern SD2 may be greater that an height of the third source/drain pattern SD3.

For example, the first source/drain pattern SD1 may have a greater size than the second source/drain pattern SD2, and may have a smaller size than the third source/drain pattern SD3. For another example, the first source/drain pattern SD1 may occupy a greater area in a plan view than the second source/drain pattern SD2, and may occupy a smaller area in the plan view than the third source/drain pattern SD3.

The gate electrode GE may be provided on the channel pattern CH, and may cross the channel pattern CH. The gate electrode GE may be provided in plurality. The gate electrodes GE may be spaced apart from each other in an extension direction of the active pattern AP, and may each extend in a direction crossing the extension direction of the active pattern AP.

The gate electrode GE may include inner electrodes PO1 and an outer electrode PO2. The inner electrode POI of the gate electrode GE may be provided between the active pattern AP and an uppermost semiconductor pattern among a plurality of semiconductor patterns SP1, SP2, and SP3. The outer electrode PO2 of the gate electrode GE may be provided on the uppermost semiconductor pattern. For example, the inner electrode PO1 of the gate electrode GE may include three electrode portions, but the inventive concept is not limited thereto. For example, the inner electrode PO1 of the gate electrode GE may include at least four electrode portions.

The gate electrode GE may include a first metal pattern, and a second metal pattern on the first metal pattern. The first metal pattern may be a work-function metal that controls a threshold voltage of a transistor. For example, the first metal pattern may include at least one of a metal material (for example, Ti, Mo, W, Cu, Al, Ta, Ru, Ir, Co, or the like), or a metal nitride (for example, a nitride of Ti, Mo, W, Cu, Al, Ta, Ru, Ir, Co, or the like). For example, the first metal pattern may further include carbon (C). For example, the first metal pattern may include metal material having different work-function from the second metal pattern.

The first and second metal patterns of the gate electrodes GE may include metal material having different work-function from each other. For example, the second metal pattern may include a metal material (for example, Ti, Mo, W, Cu, Al, Ta, Ru, Ir, Co, or the like) having a lower resistance than the first metal pattern.

For example, the inner electrode POI of the gate electrode GE may include the first metal pattern. For example, the outer electrode PO2 of the gate electrode GE may include both the first metal pattern and the second metal pattern.

A gate capping pattern GC may be provided on the upper surface of the gate electrode GE. For example, the gate capping pattern GC may include at least one of SiON, SiCN, SiOCN, or SiN.

Gate spacers GS may be provided on side surfaces of the outer electrode PO2 of the gate electrode GE, and may respectively extend onto side surfaces of the gate capping pattern GC. The gate spacers GS may include single film or composite film. For example, the gate spacer GS may include at least one of SiON, SiCN, SiOCN, or SiN.

A gate insulating pattern GI may be interposed between the gate electrode GE and the first to third semiconductor patterns SP1, SP2, and SP3. The gate insulating pattern GI may cover an upper surface, a bottom surface, and a pair of side surfaces of each of the first to third semiconductor patterns SP1, SP2, and SP3. The gate insulating pattern GI may be interposed between the outer electrode PO2 and the gate spacer GS. The gate insulating pattern GI may be in contact with the first to third source/drain patterns SD1 to SD3. For example, the gate insulating pattern GI may include at least one of silicon oxide (SiO2), silicon oxynitride (SiON) or a high dielectric material. In the present disclosure, the high dielectric material is defined as a material having a higher dielectric constant than silicon oxide.

An inner spacer (not shown) may be interposed between the source/drain pattern SD and the gate insulating pattern GI provided on the second active pattern AP2.

A first interlayer insulating layer ILDI may be provided on the substrate 100. The first interlayer insulating layer ILD1 may cover the gate spacers GS and the source/drain pattern SD. For example, an upper surface of the first interlayer insulating layer ILD1 may be located at the substantially same level as an upper surface of the gate capping pattern GC and an upper surface of the gate spacer GS.

A second interlayer insulating layer ILD2 may cover the gate capping pattern GC on the first interlayer insulating layer ILD1. A third interlayer insulating layer ILD3 may be provided on the second interlayer insulating layer ILD2. For example, the first to third interlayer insulating layers ILD1, ILD2, and ILD3 may include silicon oxide (SiO2).

Each of active contacts CA may penetrate the first and second interlayer insulating layers ILD1 and ILD2. A lower portion of each of the active contacts CA may be buried in an upper portion of the source/drain pattern SD such that an upper trench in each of the source/drain patterns SD accommodates the lower portion of a corresponding one of the active contacts CA. For example, the active contacts CA may include at least one of a metal material (for example, Ti, Mo, W, Cu, Al, Ta, Ru, Ir, Co, or the like), a metal silicide (for example, a silicide of Ti, Mo, W, Cu, Al, Ta, Ru, Ir, or the like), or a metal nitride (for example, a nitride of Ti, Mo, W, Cu, Al, Ta, Ru, Ir, Co, or the like).

Gate contacts (not shown) may penetrate the second interlayer insulating layer ILD2 and the gate capping pattern GC along the third direction D3. Each of the gate contacts may be buried in an upper portion of the outer electrode PO2 of the gate electrode GE. For example, the gate contacts may include at least one of a metal material (for example, Ti, Mo, W, Cu, Al, Ta, Ru, Ir, Co, or the like), or a metal nitride (for example, a nitride of Ti, Mo, W, Cu, Al, Ta, Ru, Ir, Co, or the like).

Metal patterns MT may be provided in the third interlayer insulating layer ILD3. Via patterns VIA may be interposed between the metal patterns MT and the active contacts CA, and between the metal patterns MT and gate contacts. For example, although not shown, the metal pattern MT and the via pattern VIA may be each provided as a plurality of layers, and may be alternately stacked. The metal patterns MT and the via patterns VIA may include a metal material (for example, Ti, Mo, W, Cu, Al, Ta, Ru, Ir, Co, or the like).

Power may be supplied to the source/drain pattern SD through lines and contacts (for example, the metal patterns MT and the via patterns VIA) provided in the first to third interlayer insulating layers ILD1, ILD2 and ILD3, but the inventive concept is not limited thereto. For another example, separate lines and contacts may be buried in the substrate 100, or may be provided on a lower surface of the substrate 100. Accordingly, the power (for example, a source voltage or drain voltage) may be supplied to the source/drain pattern SD through a rear surface of the substrate 100.

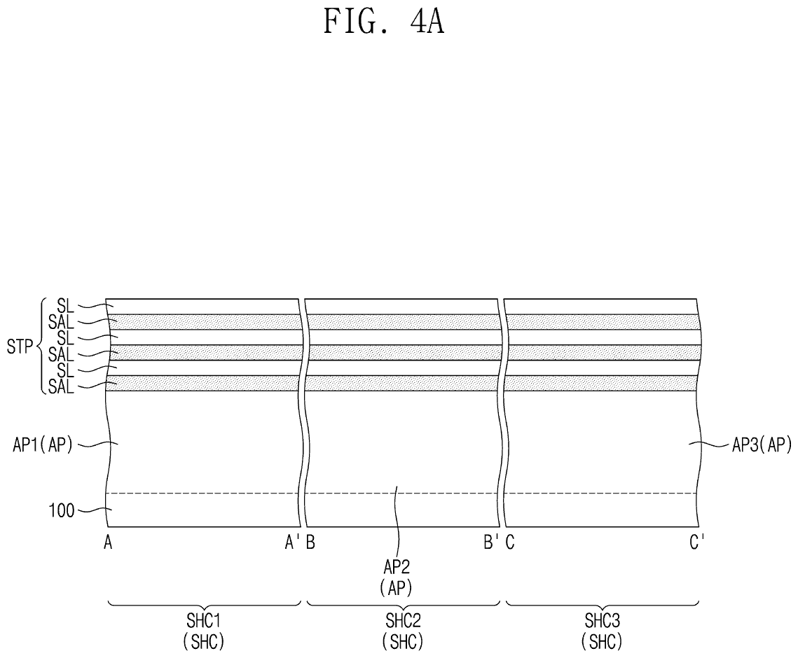

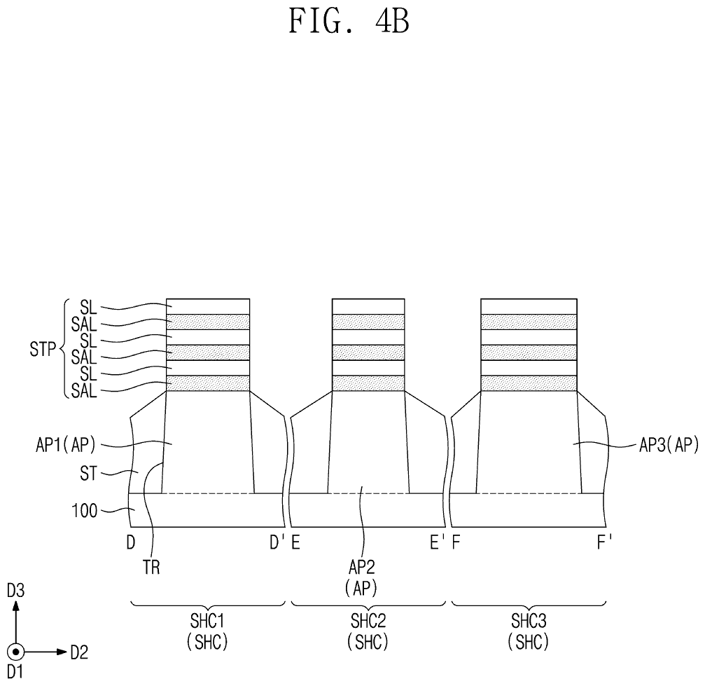

Hereinafter, a method for manufacturing a semiconductor device according to some embodiments of the inventive concept will be described with reference to FIGS. 4A to 7. For simplification of description, duplicate description of items described above will be omitted, and a difference from that described above will be mainly described.

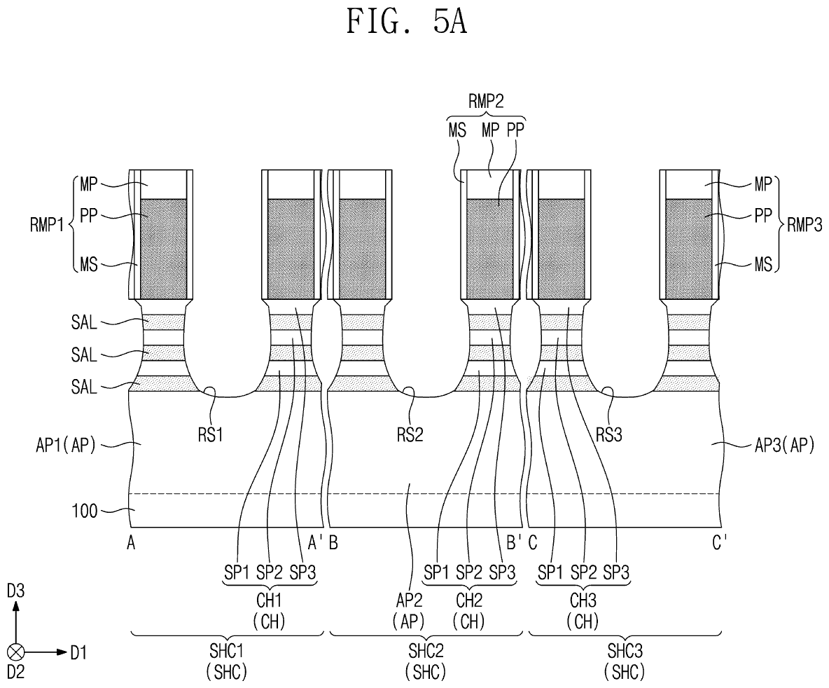

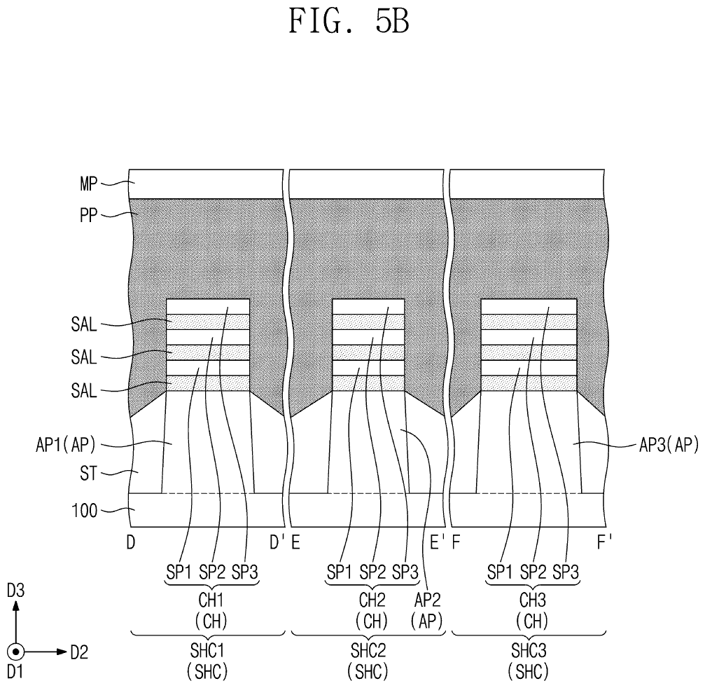

FIGS. 4A to 7 are diagrams illustrating the method for manufacturing a semiconductor device according to some embodiments of the inventive concept. More specifically, FIGS. 4A, 5A, 6 and 7 are each a cross-sectional view taken along line A-A′, line B-B′, and line C-C′ in FIG. 1. FIGS. 4B and 5B are each a cross-sectional view taken along line D-D′, line E-E′ and line F-F′ of FIG. 1.

Referring to FIGS. 1, 4A and 4B, a substrate 100 including first and second active regions AR1 and AR2 may be provided. Stack patterns STP may be formed on the first and second active regions AR1 and AR2. For example, forming the stack patterns STP may include alternately stacking of semiconductor layers SL and sacrificial layers SAL on the substrate 100, forming mask patterns (not shown) extending in the first direction D1, and performing a patterning process by using the mask patterns as etching masks. When the patterning process is performed, the substrate 100 may be partially removed together, and trenches TR may be formed. Element isolation patterns ST may be formed to fill the trenches TR. As a result of the process of forming the trenches TR, along the second direction D2, a width (which may correspond to the first width W1 of FIG. 3) of an upper surface of the stack pattern STP of a first single height cell SHC1 may be greater than a width (which may correspond to the second width W2 of FIG. 3) of an upper surface of the stack pattern STP of a second single height cell SHC2, and may be smaller than a width (which may correspond to the third width W3 of FIG. 3) of an upper surface of the stack pattern STP of a third single height cell SHC3.

The sacrificial layers SAL may include a material capable of having etching selectivity for the semiconductor layers SL. Accordingly, when a process of removing the sacrificial layers SAL (to be described later) is performed, the sacrificial layers SAL may be removed, but the semiconductor layers SL may not be removed or may be removed less than the sacrificial layers SAL. For example, the semiconductor layers SL may include one of silicon (Si), germanium (Ge), and silicon-germanium (SiGe). The sacrificial layers SAL may be or include different material from that of the semiconductor layers SL. The sacrificial layers SAL may include one of silicon (Si), germanium (Ge), and silicon-germanium (SiGe).

Referring to FIGS. 1, 5A and 5B, sacrificial patterns PP may be formed to extend along the second direction D2 on the substrate 100. The sacrificial patterns PP may be formed to cover upper surfaces of the element isolation patterns ST, side surfaces and upper surfaces of the stack patterns STP. For example, forming the sacrificial patterns PP may include forming a sacrificial film (not shown) on a front side (upper surface) of the substrate 100, forming hard mask patterns MP on the sacrificial film, and forming the sacrificial patterns PP by partially removing the sacrificial film by using the hard mask patterns MP as etching masks. For example, the sacrificial patterns PP may include polysilicon. Thereafter, mask spacers MS may be formed on side surfaces of the sacrificial patterns PP.

The sacrificial pattern PP, the mask pattern MP and the mask spacer MS formed in the first single height cell SHC1 may constitute a first recess mask pattern RMP1. The sacrificial pattern PP, the mask pattern MP and the mask spacer MS formed in the second single height cell SHC2 may constitute a second recess mask pattern RMP2. The sacrificial pattern PP, the mask pattern MP and the mask spacer MS formed in the third single height cell SHC3 may constitute a third recess mask pattern RMP3.

The first to third recess mask patterns RMP1, RMP2 and RMP3 may be formed at different times. For example, when the first recess mask pattern RMP1 is formed, the second and third recess mask patterns RMP2 and RMP3 may not be formed. In this case, the first recess mask pattern RMP1 may be formed to cover, in a plan view, the areas of the second single height cell SHC2 and the third single height cell SHC3. Similarly, when the second recess mask pattern RMP2 is formed, the first and third recess mask patterns RMP1 and RMP3 may not be formed. In this case, the second recess mask pattern RMP2 may be formed to cover, in a plan view, the areas of the first single height cell SHC1 and the third single height cell SHC3. When the third recess mask pattern RMP3 is formed, the first and second recess mask patterns RMP1 and RMP2 may not be formed. In this case, the third recess mask pattern RMP3 may be formed to cover, in a plan view, the areas of the first single height cell SHC1 and the second single height cell SHC2. A sequence of processes of forming the first to third recess mask patterns RMP1, RMP2 and RMP3 may be variously changed by those skilled in the art.

First recesses RS1 may be formed by partially removing the stack pattern STP on (in the area of) the first single height cell SHC1 by using the first recess mask pattern RMP1 as an etching mask. In this case, the stack pattern STP, entirely covered by the first recess mask pattern RMP1, may not be removed. For example, when the first recesses RS1 are formed, the stack pattern STP, provided in each areas of the second single height cell SHC2 and the third single height cell SHC3, also may not be removed. The semiconductor layers SL on the first active pattern AP1 of the first single height cell SHC1 may be separated into the first channel patterns CH1 spaced apart from each other in the first direction D1 by the first recesses RS1.

Second recesses RS2 may be formed by partially removing the stack pattern STP on the second single height cell SHC2 by using the second recess mask pattern RMP2 as an etching mask. In this case, the stack pattern STP, entirely covered by the second recess mask pattern RMP2, may not be removed. For example, when the second recesses RS2 are formed, the stack pattern STP, provided in the each area of the first single height cell SHC1 and the third single height cell SHC3, also may not be removed. The semiconductor layers SL on the second active pattern AP2 of the second single height cell SHC2 may be separated into the second channel patterns CH2 spaced apart from each other in the first direction D1 by the second recesses RS2.

Third recesses RS3 may be formed by partially removing the stack pattern STP on the third single height cell SHC3 by using the third recess mask pattern RMP3 as an etching mask. In this case, the stack pattern STP, entirely covered by the third recess mask pattern RMP3 may not be removed. For example, when the third recesses RS3 are formed, the stack pattern STP, provided in the each area of the first single height cell SHC1 and the second single height cell SHC2, also may not be removed. The semiconductor layers SL on the third active pattern AP3 of the third single height cell SHC3 may be separated into the third channel patterns CH3 spaced apart from each other in the first direction D1 by the third recesses RS3.

The first recess RS1, the second recess RS2 and the third recess RS3 may be formed at different times by different processes. A sequence of the process of forming the first recess RS1, the process of forming the second recess RS2 and the process of forming the third recess RS3 may be variously changed by those skilled in the art.

Along the second direction D2 the widths of the first to third recesses RS1, RS2 and RS3 in the areas of the first to third single height cells SHC1, SHC2 and SHC3 respectively may be formed differently from each other due to differences in widths of the stack patterns STP as described above in connection with FIGS. 4A and 4B. For example, along the second direction D2, the width of the first recess RS1 may be formed to be greater than the width of the second recess RS2, and to be smaller than the width of the third recess RS3. Accordingly, an inner space (a volume) of the first recess RS1 may be greater than an inner space of the second recess RS2, and may be smaller than an inner space of the third recess RS3. The inner space may be defined as a space filled with a source/drain pattern SD in a process of forming the source/drain pattern SD to be described later.

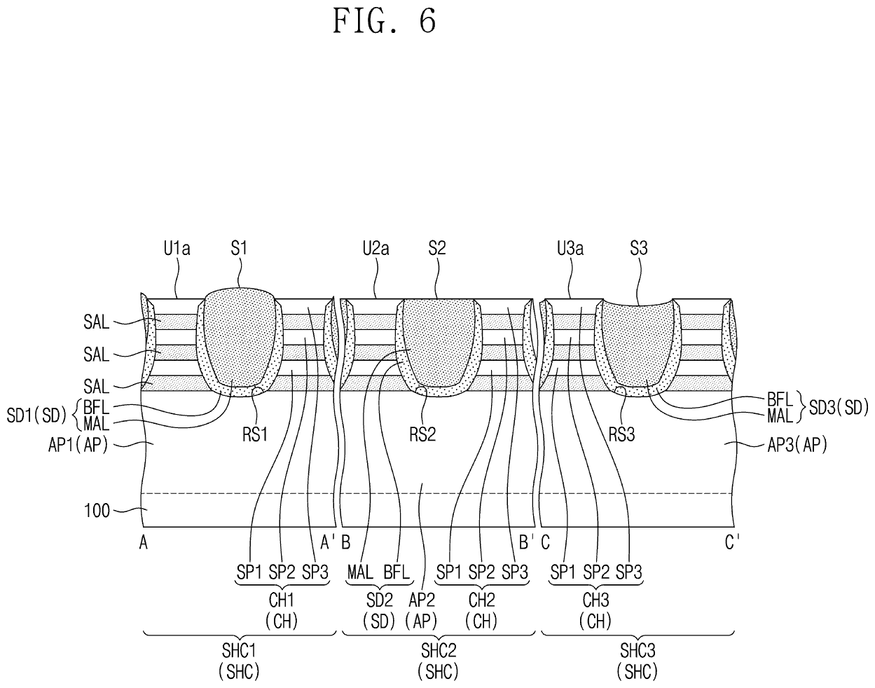

Referring to FIGS. 1 and 6, after the last process among the process of forming the first recess RS1, the process of forming the second recess RS2 and the process of forming the third recess RS3, the mask pattern (in other words, one of the first to third recess mask patterns RMP1, RMP2 and RMP3) used in the last process may be removed.

Thereafter, a first source/drain pattern SD1 may be formed to fill the first recess RS1, a second source/drain pattern SD2 may be formed to fill the second recess RS2 and a third source/drain pattern SD3 may be formed to fill the third recess RS3. For example, the first to third source/drain patterns SD1 to SD3 may be formed through a selective epitaxial growth (SEG) process by using the sacrificial layers SAL as seeds. Processes of forming the first to third source/drain patterns SD1 to SD3 may not be performed at different times. In some embodiments of the invention, the processes of forming the first to third source/drain patterns SD1 to SD3 may be simultaneously performed.

When the processes of forming the first to third source/drain patterns SD1 to SD3 are simultaneously performed, the first source/drain pattern SD1 may overgrow, and the second and third source/drain patterns SD2 and SD3 may undergrow the first source/drain pattern SD1. When an upper surface of a source/drain pattern is formed to be located at a vertically higher level than an upper surface of a channel pattern, the source/drain pattern may be overgrown. When the source/drain patterns SD1 to SD3 undergo undergrowth, the epitaxy growth rate may be lower compared to when the source/drain patterns SD1 to SD3 are overgrown. For example, if the upper surface of a source/drain pattern is formed at a vertically higher level than other source/drain patterns, it may be considered overgrown.

A reason why the third source/drain pattern SD3 undergrows the first source/drain pattern SD1 at the same selective epitaxial growth (SEG) process condition is that the inner space of the third recess RS3 is greater than the inner space of the first recess RS1. A reason why the second source/drain pattern SD2 undergrows the first source/drain pattern SD1 at the same selective epitaxial growth (SEG) process condition is that the inner space of the second recess RS2 is smaller than the inner space of the first recess RS1, and thus source materials supplied in the selective epitaxial growth (SEG) process enter the second recess RS2 less than the first recess RS1. The third source/drain pattern SD3 may undergrow due to the larger inner space of the third recess RS3 compared to the first recess RS1. Similarly, the second source/drain pattern SD2 may undergrow because the second recess RS2 has a smaller inner space than that of the first recess RS1. During the selective epitaxial growth (SEG) process, fewer source materials may be supplied to the second recess RS2 than the first recess RS1.

According to the inventive concept, the processes of forming the first to third source/drain patterns SD1 to SD3 may be simultaneously performed. In this case, the first source/drain pattern SD1 may overgrow compared to the second and third source/drain patterns SD2 and SD3. For example, the first source/drain pattern SD1 may be formed such that a first upper surface S1 thereof is located at a vertically higher level than an upper surface Ula of the first channel pattern CH1. The second source/drain pattern SD2 may be formed such that a second upper surface S2 thereof is located at the substantially vertically same level as an upper surface U2a of the second channel pattern CH2. Moreover, the third source/drain pattern SD3 may be formed such that a third upper surface S3 thereof is located at a vertically lower level than an upper surface U3a of the third channel pattern CH3, thereby securing a sufficient thickness to sufficiently secure a region of the third source/drain pattern SD3 overlapping the uppermost semiconductor pattern SP3 with respect to a side view (e.g., as viewed from the direction D1 shown in FIG. 2). For example, the processes of forming the first to third source/drain patterns SD1 to SD3 may be simultaneously performed such that each of the first to third source/drain patterns SD1 to SD3 have sufficient contact area to a corresponding one of the uppermost semiconductor patterns SP3. Unlike the manufacturing method according to the inventive concept, when the first source/drain pattern SD1 is formed such that the upper surface S1 thereof is located at the substantially vertically same level as the upper surface U1a of the first channel pattern CH1, degrees of undergrowth of the second and third source/drain patterns SD2 and SD3 may become greater. Accordingly, the performance and characteristics of each of the second single height cell SHC2 and the third single height cell SHC3 may be degraded. According to the inventive concept, electrical characteristics of the semiconductor device may be improved by solving such a limitation. For example, each of the first to third source/drain patterns SD1 to SD3 have sufficient contact area to a corresponding one of the uppermost semiconductor patterns SP3, while limiting the degree of overgrowth of the first source/drain patterns SD1 and undergrowth of the third source/drain patterns SD3 within an acceptable range. Accordingly, any problems resulting from the overgrowth and/or undergrowth may be significantly reduced.

When the processes of forming the first to third source/drain patterns SD1 to SD3 may be performed at different times through separate different processes, though the first to third source/drain patterns SD1 to SD3 may be formed such that the upper surface of each thereof is located at the substantially vertically same level as the upper surface of each of the first to third channel patterns CH1, CH2 and CH3, a number of the processes of forming the first to third source/drain patterns SD1 to SD3 may increase. As a result, productivity of the semiconductor device may be reduced.

On the other hand, according to the inventive concept, since the processes of forming the first to third source/drain patterns SD1 to SD3 in the first to third recesses RS1, RS2 and RS3 are simultaneously performed, the number of the processes may be reduced. As a result, the method for manufacturing the semiconductor device may be simplified. In other words, according to the inventive concept, the electrical characteristics and the productivity of the semiconductor device may be simultaneously improved.

For example, when the first to third source/drain patterns SD1 to SD3 are formed, a P-type impurity (for example, boron, gallium, or indium) may be in-situ injected to the first to third source/drain patterns SD1 to SD3. For example, during the growth of the first to third source/drain patterns SD1 to SD3, charge carrier dopants may be introduced simultaneously. For another example, after the first to third source/drain patterns SD1 to SD3 are formed, the impurity may be injected to the first to third source/drain patterns SD1 to SD3.

Although not shown, a recess (not shown) may be formed by partially removing a stack pattern (not shown) on the second active region AR2. The source/drain pattern SD may be formed to fill the recess. When the source/drain pattern SD is formed, an N-type impurity (for example, phosphorous, arsenic or antimony) may be in-situ injected to the source/drain pattern SD. For another example, after the source/drain pattern SD is formed, the impurity may be injected into the source/drain pattern SD.

In some embodiments, before removing of the mask patterns RMP1, RMP2 and RMP3, the first to third source/drain patterns SD1, SD2 and SD3 may be formed to fill the first to third recesses RS1, RS2 and RS3.

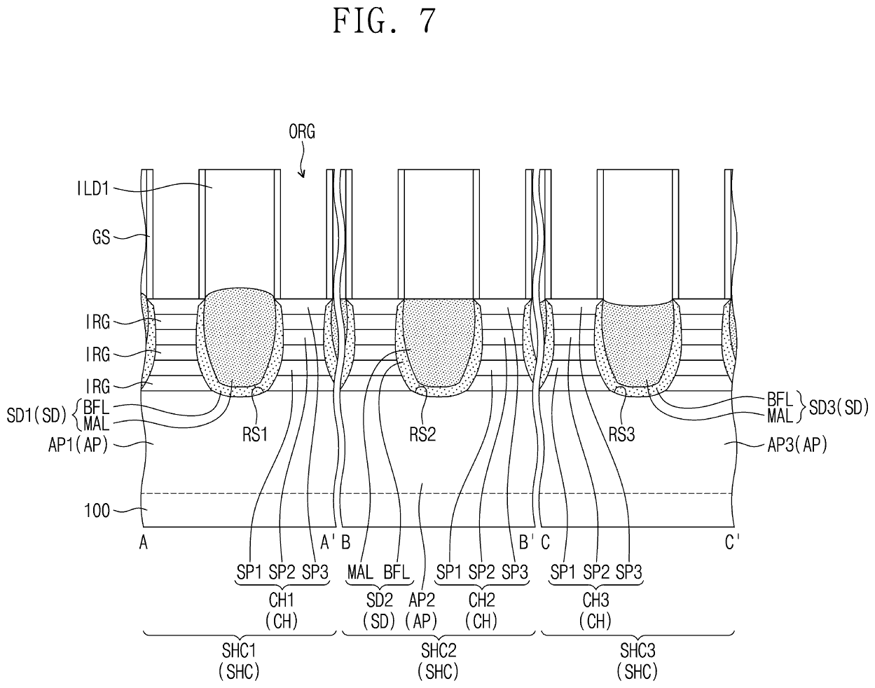

Referring to FIGS. 1 and 7, a first interlayer insulating layer ILD1 and a gate spacer GS may be formed. An outer region ORG may be defined (formed) between the gate spacers GS such that a portion of the sacrificial layers SAL is exposed.

The sacrificial layers SAL exposed by the outer region ORG may be selectively removed. In this case, the first to third semiconductor patterns SP1, SP2, and SP3 may not be removed or may be removed less due to high etching selectivity for the sacrificial layers SAL.

Inner regions IRG may be formed in a region in which the sacrificial layers SAL are removed. Specifically, the inner region IRG may be formed between the first to third semiconductor patterns SP1, SP2, and SP3.

Referring to FIGS. 1, 2 and 3, a gate insulating pattern GI may be formed in each of the inner regions IRG (see FIG. 6) and the outer region ORG (see FIG. 6). The gate insulating pattern GI may be formed to surround each of the first to third semiconductor patterns SP1, SP2, and SP3.

A gate electrode GE may be formed on the gate insulating pattern GI. The gate electrode GE may include an inner electrode PO1 formed in each of the inner regions IRG and an outer electrode PO2 formed in the outer region ORG. Thereafter, a gate capping pattern GC may be formed on the outer electrode PO2 of the gate electrode GE.

A second interlayer insulating layer ILD2 may be formed on the gate capping pattern GC and the first interlayer insulating layer ILD1.

Active contacts CA may be formed to penetrate the first interlayer insulating layer ILD1 and the second interlayer insulating layer ILD2, and may be connected to the source/drain patterns SD.

Gate contacts (not shown) may be formed to penetrate the second interlayer insulating layer ILD2 and the gate capping pattern GC, and may be connected to the gate electrodes GE.

A third interlayer insulating layer ILD3 may be formed on the second interlayer insulating layer ILD2. Metal patterns MT and via patterns VIA may be formed in the third interlayer insulating layer ILD3.

According to the inventive concept, processes of forming source/drain patterns of first to third single height cells may be simultaneously performed. In this case, the source/drain pattern of the first single height cell may be overgrown as compared to the source/drain pattern of each of the second single height cell and the third single height cell. For example, the source/drain pattern of the first single height cell may be formed such that an upper surface thereof is located at a vertically higher level than an upper surface of a channel pattern.

Unlike a manufacturing method according to the inventive concept, when the source/drain pattern of the first single height cell is formed such that the upper surface thereof is located at the substantially vertically same level as the upper surface of the channel pattern, a degree of undergrowth of the source/drain pattern of each of the second single height cell and the third single height cell may become greater. Accordingly, element characteristics of each of the second single height cell and the third single height cell may be degraded. According to the inventive concept, electrical characteristics of a semiconductor device may be improved by solving such a limitation.

Moreover, since the processes of forming the source/drain patterns of the first to third single height cells are simultaneously performed, a number of the processes may be reduced. As a result, the method for manufacturing the semiconductor device may be simplified, and productivity of the semiconductor device may be improved.

The above description of embodiments of the inventive concept provides an example for description of the inventive concept. Therefore, the inventive concept is not limited to the above embodiments, and it is obvious that various modifications and changes such as combining the above embodiments may be made by those skilled in the art within the technical spirit of the inventive concept.

What is claimed is:

1. A semiconductor device comprising:
a first active pattern and a second active pattern provided with a substrate;
a first source/drain pattern and a first channel pattern on the first active pattern;
a second source/drain pattern and a second channel pattern on the second active pattern; and
a gate electrode crossing each of the first channel pattern and the second channel pattern,
wherein:
along a horizontal extension direction of the gate electrode, a first width of an upper surface of the first channel pattern is greater than a second width of an upper surface of the second channel pattern, and
an upper surface of the first source/drain pattern is located at a vertically higher level than the upper surface of the first channel pattern.

2. The semiconductor device of claim 1, further comprising:
a third active pattern provided with the substrate; and
a third source/drain pattern and a third channel pattern on the third active pattern,
wherein:
the gate electrode crosses the third channel pattern, and
along the horizontal extension direction of the gate electrode, a third width of an upper surface of the third channel pattern is greater than the first width.

3. The semiconductor device of claim 2, wherein an upper surface of the third source/drain pattern is located at a vertically lower level than the upper surface of the third channel pattern.

4. The semiconductor device of claim 2, wherein the upper surface of the first source/drain pattern is located at a vertically higher level than an upper surface of the third source/drain pattern.

5. The semiconductor device of claim 2, wherein:
an upper surface of the second source/drain pattern is located at a vertically lower level than the upper surface of the first source/drain pattern, and
the upper surface of the second source/drain pattern is located at a vertically higher level than an upper surface of the third source/drain pattern.

6. The semiconductor device of claim 2, wherein an upper surface of the third source/drain pattern has a concave downward profile.

7. The semiconductor device of claim 1, wherein an upper surface of the second source/drain pattern is located at the same vertical level as the upper surface of the second channel pattern.

8. The semiconductor device of claim 1, wherein the upper surface of the first source/drain pattern is located at a vertically higher level than an upper surface of the second source/drain pattern.

9. The semiconductor device of claim 1, wherein the upper surface of the first source/drain pattern has a convex upward profile.

10. The semiconductor device of claim 1, wherein the first and second source/drain patterns each comprise SiGe.

11. The semiconductor device of claim 10, wherein:
the first and second source/drain patterns each comprise a main layer and a buffer layer,
the main layer has a greater SiGe atomic concentration than the buffer layer, and
the buffer layer is disposed to partially surround the main layer.

12. The semiconductor device of claim 1, further comprising a gate insulating pattern between the first source/drain pattern and the gate electrode, and between the second source/drain pattern and the gate electrode,
wherein the gate insulating pattern is in contact with each of the first source/drain pattern and the second source/drain pattern.

13. A semiconductor device comprising:
a first active pattern and a second active pattern provided with a substrate;
a first source/drain pattern and a first channel pattern on the first active pattern;
a second source/drain pattern and a second channel pattern on the second active pattern; and
a gate electrode crossing each of the first channel pattern and the second channel pattern,
wherein:
along a horizontal extension direction of the gate electrode, a first width of an upper surface of the first channel pattern is smaller than a second width of an upper surface of the second channel pattern, and
an upper surface of the first source/drain pattern is located at a vertically higher level than the upper surface of the first channel pattern.

14. The semiconductor device of claim 13, further comprising:
a third active pattern provided with the substrate; and
a third source/drain pattern and a third channel pattern on the third active pattern,
wherein:
the gate electrode crosses the third channel pattern, and
along the horizontal extension direction of the gate electrode, a third width of an upper surface of the third channel pattern is smaller than the first width.

15. The semiconductor device of claim 14, wherein an upper surface of the third source/drain pattern is located at the same vertical level as the upper surface of the third channel pattern.

16. The semiconductor device of claim 14, wherein:
an upper surface of the third source/drain pattern is located at a vertically lower level than the upper surface of the first source/drain pattern, and
the upper surface of the third source/drain pattern is located at a vertically higher level than an upper surface of the second source/drain pattern.

17. The semiconductor device of claim 13, wherein an upper surface of the second source/drain pattern is located at a vertically lower level than the upper surface of the second channel pattern.

18. The semiconductor device of claim 13, wherein:
the upper surface of the first source/drain pattern has a convex upward profile, and
an upper surface of the second source/drain pattern has a concave downward profile.

19. The semiconductor device of claim 13, wherein:
the first and second source/drain patterns each comprise SiGe,
the first and second source/drain patterns each comprise a main layer and a buffer layer,
the main layer has a greater SiGe atomic concentration than the buffer layer, and
the buffer layer is disposed to partially surround the main layer.

20. A semiconductor device comprising:
a first active pattern and a second active pattern provided with a substrate;
a first source/drain pattern and a first channel pattern on the first active pattern;
a second source/drain pattern and a second channel pattern on the second active pattern;
a gate electrode crossing each of the first and second channel patterns;
a first interlayer insulating layer on the first source/drain pattern and the second source/drain pattern; and
an active contact penetrating the first interlayer insulating layer and connected to at least one of the first source/drain pattern or the second source/drain pattern,
wherein:
along a horizontal extension direction of the gate electrode, a first width of an upper surface of the first channel pattern is greater than a second width of an upper surface of the second channel pattern, and
an upper surface of the first source/drain pattern is located at a vertically higher level than the upper surface of the first channel pattern.
